(19) United States
(12) Patent Application Publication
(10) Pub. No.: US 2026/0065986 A1
(43) Pub. Date: Mar. 5, 2026

(54) HIDING INFORMATION IN MEMORY CELLS

(71) Applicant: Infineon Technologies AG, Neubiberg (DE)

(72) Inventors: Jan Otterstedt, Unterhaching (DE); Alexander Duch, Muenchen (DE)

(21) Appl. No.: 19/317,514

(22) Filed: Sep. 3, 2025

(30) Foreign Application Priority Data
Sep. 4, 2024 (DE) 102024208411.5

(51) Int. Cl. G11C 13/00

(52) U.S. Cl. CPC G11C 13/0059

(57) ABSTRACT

A method for hiding data in an integrated circuit that includes random-access memory cells and a write circuit for the cells. The write circuit is to selectively (i) activate a cell and apply a first physical parameter to the cell to set the cell into a first state that is identified as first state read under regular conditions, and (ii) activate a cell and apply a second physical parameter to the cell to set the cell into a second state. The second state is identified as first state under regular read condition and is identified as second state under non-regular read conditions. The method includes receiving data to be hidden and activating the write circuit to activate the cell and applying the second physical parameter to the cell depending on the received data.

### TECHNICAL FIELD

The present disclosure relates to memory cells and the data stored in the memory cells.

### BACKGROUND

RRAM (resistive random access memory) is an advanced type of non-volatile memory technology, used in a variety of products. The RRAM memory makes use of RRAM cells. A RRAM cell comprises at least two electrodes with a RRAM layer in-between. This layer may comprise HfO2 or Ta2O5 or other dielectric material. Directly after the production, the RRAM layer and thus the RRAM cell is in an isolating state (here named “ISOLATE”). The RRAM element is structured like a metal-isolator-metal (MIM) capacitor.

In a so called “forming step”, a first conductive path is generated in the RRAM layer. This forming is typically done by applying a relatively high voltage to the electrodes (e.g. 2.5V - 4.0V) until the isolation layer breaks and a current flows between the electrodes. The first conductive path may consist of filaments that form a conductive path. If the relative high voltage is turned off, these filaments are still present, such that the RRAM cell will never be in the “ISOLATE” state again. The “ISOLATE” state may also be called “UNFORMED” state.

When this first conductive path has been formed, the RRAM element can be switched between a relatively low resistive state and a relatively high resistive state by applying lower voltages (e.g. 1.5V-2.5V) of respective polarities. These two states are typically named “SET” state and “RESET” state and are used to store data in the RRAM memory. If e.g. cells in the SET state represent logic ‘1’s and cells in the RESET state represent logic ‘0’s, data may be stored by applying the respective voltages to the cells. If there is a low-resistive conductive path through the dielectric, the state is called SET. The low-resistive path may arise from different mechanisms and may be formed homogenously or by distributed filaments. The low-resistance path may be broken resulting in a high resistance between the electrodes by the step called resetting. In this case, the cell gets into the RESET state. Setting and resetting may be done by applying predetermined voltages to the electrodes of the cells. This step can also be called programming of the cell.

The states of the cells can be read by applying a relatively small voltage, e.g.

100 mV to 500 mV, to the cell and measuring the current flowing through the cell between the electrodes. If the current is above a first predetermined threshold, the state is considered to be SET. If the current is below a second predetermined threshold, the state is considered to be RESET. However, this is just an exemplary aspect. Others may comprise comparing currents of memory cells with currents through reference cells.

### SUMMARY

A method is disclosed for hiding data in an integrated circuit that comprises random-access memory cells and a write circuit for the cells. The write circuit is capable of selectively (i) activating a cell and applying a first physical parameter to the cell to set the cell into a first state that is identified as first state read under regular conditions, and (ii) activating a cell and applying a second physical parameter to the cell to set the cell into a second state.

The second state is identified as first state under regular read condition and is identified as second state under non-regular read conditions. The method comprises the step of receiving data to be hidden and activating the write circuit to activate the cell and applying the second physical parameter to the cell depending on the received data.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a read circuit in a device under regular conditions.

FIG. 2 shows the read circuit in the device under non-regular conditions.

FIG. 3 shows a comparison circuit for the read circuit of FIG. 2.

FIG. 4 shows a method for a read under regular read conditions.

FIG. 5 discloses a second aspect of an apparatus comprising a read circuit.

FIG. 6 disclosures a method for hiding information.

### DETAILED DESCRIPTION

The examples described herein provide a device and a method for reading data from memory cells.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred aspects as outlined in the present document may be used stand-alone or in combination with the other methods and devices disclosed in this document. In addition, the features outlined in the context of a device are also applicable to a corresponding method, and vice versa.

Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and aspects outlined in the present document are principally intended expressly to be only for explanatory purposes to help the reader in understanding the principles of the proposed methods and systems. Furthermore, all statements herein providing principles, aspects, and aspects of the invention, as well as specific examples thereof, are intended to encompass equivalents thereof.

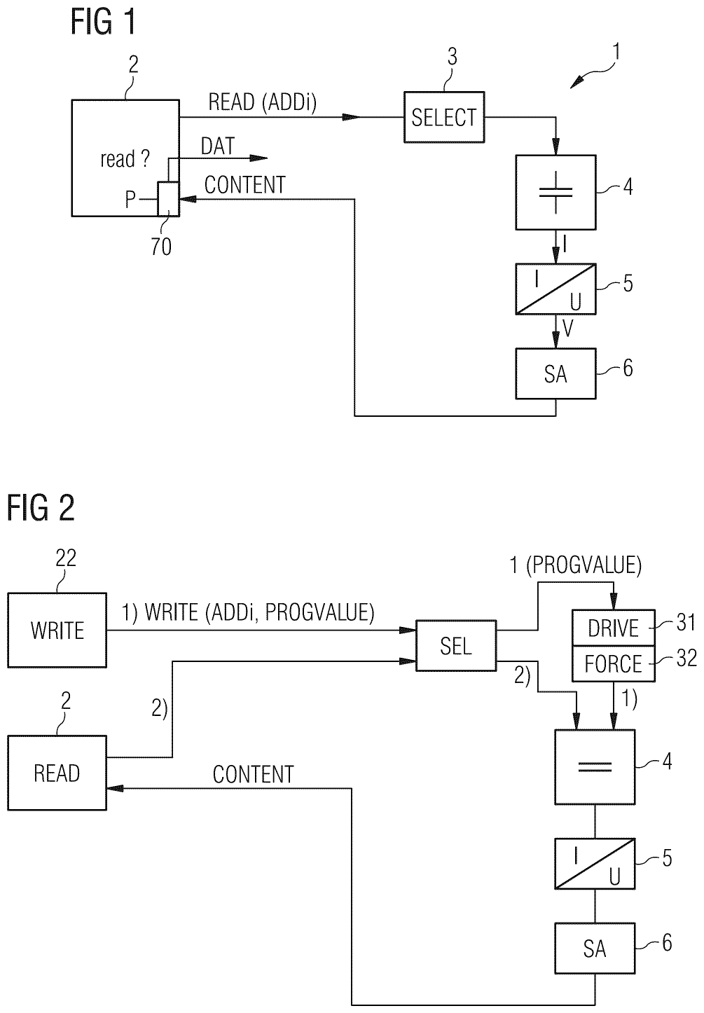

FIG. 1 illustrates a read circuit 2 in an integrated circuit 1. The integrated circuit 1 comprises a read circuit 2, a selection circuit 3, a memory cell 4, a current to voltage converter 5 and a sense amplifier 6. The read circuit 2 issues a read command together with a specific address ADDI, which indicates a specific memory cell 4 or block of cells 4, to the selection circuit 3.

The selection circuit 3 selects the cell 4 respectively block of cells 4 associated with the specific address and activates the cell 4 respectively cells 4. In the following, the term “a cell” will be used even if a block of cells 4 is activated in parallel at each read or write access.

The resistive memory cell 4 is activated, typically with a help of a selection transistor (not shown), such that a current may flow through a filament in the dielectric material, depending on the state of the cell 4. If the cell is in a SET state, a high current flows though the cell. The current is low if the cell is in the RESET state. SET and RESET are called first states. In aspects, there may be a plurality of SET states, like SET1, SET2, SET3, each providing a different current level such that the signal provided by the current is not binary, but may have more than two values. The current through the selected cell 4 is received by the current-to-voltage converter 5, which outputs a voltage to the sense amplifier 6. In other aspects, the current-to-voltage converter 5 and the sense amplifier 6 are embodied in one circuit. The sense amplifier 6 outputs a digital value CONTENT. The CONTENT is a representation of the state of the read memory cell 4, if the current-to-voltage converter 5 and the sense amplifier 6 work properly. The regular read conditions are used in the usual operation in the field, e.g. when the integrated circuit is used in a smartcard during the process of paying with the card.

Apart from the “ISOLATE” state, the SET state(s) and the RESET state, one or two additional second states “OVERSET” and/or “OVERRESET” are introduced. These new, second states, at least under regular operating conditions, cannot be distinguished from the respective normal states during read operations: “OVERSET” looks like “SET”, “OVERRESET” looks like “RESET” and “ISOLATE”. If an “OVERSET” cell is read, the cell is read as “SET”and if a “OVERRESET”is read, the cell is read as “RESET”.

Only under special operating conditions, “OVERSET” can be distinguished from “SET” and “OVERRESET” can be distinguished from “RESET” or “ISOLATE”. This fact is used to hide additional information “in plain sight”.

Setting a cell into a first state like SET or RESET is done by activating a cell 4 and applying a first physical parameter to the cell 4 to set the cell 4. The state of the first cell is identified as first state under regular read conditions. The first physical parameter may be applied by forcing an electrical voltage having a predetermined amount, e.g. 3 V and a given polarity.

To set the cell 4 into a second state, a cell 4 is activated and a second physical parameter is applied to the cell 4 to set the cell 4. The second state (OVERSET, OVERRESET) is identified as first state under regular read condition and is identified as second state under non-regular read conditions. The second physical parameter may be a voltage that is higher than the first physical parameter, e.g. 4 V. In various aspects, first and second physical parameter differ in current, charge and/or duration of exposure.

The OVERSET state can be generated either from an RRAM element in RESET state or in normal SET state by applying a stronger than normal set pulse, i.e. with the same polarity, but with a higher voltage and/or for a longer time and/or with no or a less strict current limitation.

If the OVERSET state of the RRAM element is reached, other than for the normal SET state, applying a (normal) reset pulse is not sufficient to revert the state back to the SET or RESET state. Ideally, even a stronger than normal reset pulse is not sufficient either: In this case, the OVERSET state is permanently frozen. A cell in an OVERSET state cannot be reset.

The conditions for the OVERRESET state are similar, just with reversed roles:

The OVERRESET state can be generated either from an RRAM element in SET state or in normal RESET state by applying a stronger than normal reset pulse, i.e. with the same polarity, but with a higher voltage and/or for a longer time and/or with no or a less strict current limitation.

If the OVERRESET state of the RRAM element is reached, applying a normal (regular) set pulse is not sufficient, other than for the normal RESET state, to revert the state back to the RESET or SET state. Ideally, even a stronger than normal set pulse is not sufficient either: In this case the OVERRESET state is permanently frozen.

If, in a block of data, instead of only the first states “SET” and “RESET” the second state “OVERSET” is additionally used, some additional information can be encoded that cannot be detected during the normal operation of the RRAM elements.

In an example, 0 represents a RESET state, 1 represents a SET state, and $ represents an OVERSET state. In an example, a block of memory cells contains 8 cells and their states are 010$$100. Under normal read conditions, this reads as 01011100, because $ looks like 1.

The $ information is normally hidden, but it can be read out and verified by special means, which will be explained with the help of FIG. 2.

FIG. 2 shows, in the integrated circuit 1, a read circuit 2, a write circuit 22, a selection circuit 3, a drive circuit 31, a forcing circuit 32, the cell 4, a current-to-voltage converter 5 and a sense amplifier 6. Blocks with same reference numbers as in FIG. 1 may be the same blocks but be used in a different way. A read command under non-regular conditions is executed by first writing and then reading. The write command is issued with a specific address ADDI and the value that should be written into the cell, here called PROGVALUE. The selection circuit 3 selects the cell 4 respective to the address ADDI and selects their respective drive circuit 31 with the associated forcing circuit 32.

If PROGVALUE is for example RESET, the cell 4 should be reset, which means that it should transfer to a state where the resistance of the cell 4 is high. Accordingly, the drive circuit 31 uses the forcing circuit 32 to a provide high voltage of a given polarity to the cell 4, which should make the cell 4 high resistive. However, if the cell 4 has been in the OVER-SET state, the programming with the reset value fails. The high voltage is applied, but the cell 4 does not cancel the low resistance path through the dielectric layer. Thus, the programming of the cell 4 fails and the cell 4 stays in the OVER-SET state.

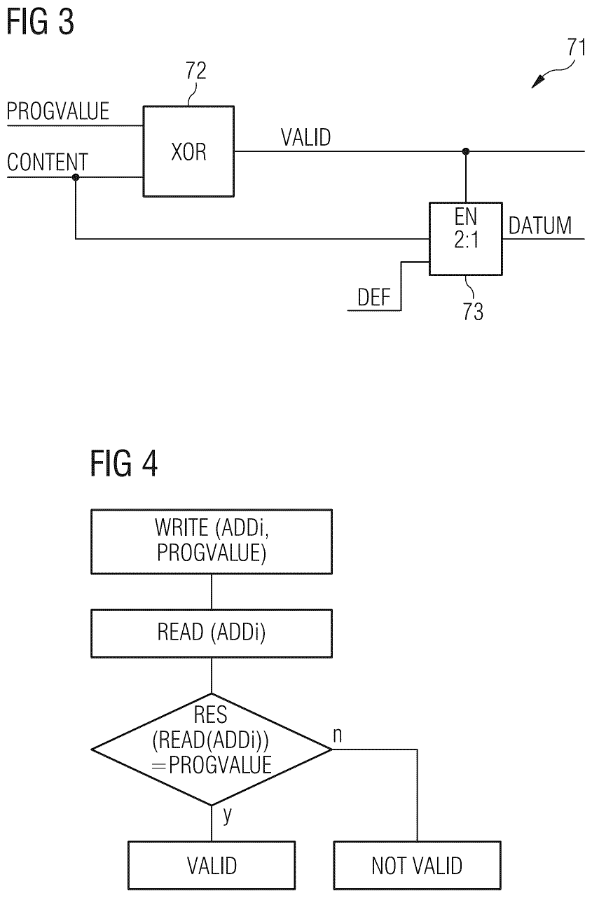

The second command is a read command, again specifying the address ADDI of the cell 4. The selecting circuit 3 selects the cell 4 according to the address delivered with the read command. The cell 4 provides a current that reflects the state of the cell 4 respectively the resistance of the dielectric layer. The OVERSET cell 4 is read as ‘1’ and the content output by the sense amplifier 6 is ‘1’. The CONTENT does not match with the written value, because the CONTENT would have to be ‘0’ to match with the intended value being PROGVALUE=“RESET”. The detection of this mismatch is done in a comparison circuit 71, which will be described with reference to FIG. 3.

In the above example, the attempt is made to reset all bits by sending a write command to all cells 4 of the block to reset all bits or at least all bits that were previously read as 1. These may be in the states 1 or $. However, only the normal SET bits are reset and, thus, a new block state is 000$$000. Under normal read conditions, the block cells are read as 00011000. Accordingly, the bits number 4 and 5 of the block contain OVERSET bits, which is now detected with the help of the read circuit 2, but under non-regular conditions because a regular read was exchanged to a sequence of write, read and compare. By this the hidden information has been revealed.

To re-hide the additional information, any other data pattern can be written to the data block, in the example of originally 010$$100, the data 11111111 or 11100111 is written, resulting in the block state 111$$111, which under normal read conditions reads as 11111111.

In a similar way, “SET” and “RESET” can be mixed with “OVERRESET”. Similarly, “SET” and “RESET” can be mixed with “OVERSET” and with “OVERRESET”.

Every chip produced may get a hidden individual marking during production testing that proves the identity of the chip, since a copied chip does not have this marking at all, or in case of a swapped chip does not have the correct marking. Note that with a correctly designed coding of the marker—like only using value pairs 0$ and $0, even adding additional OVERSET bits does not allow the generation of correct markings, since existing OVERSET bits cannot be removed.

The individual marking may represent a serial number, the lot/wafer/position on the wafer information for chip tracking, or a random number long enough to guarantee each chip has its own identifier.

Even though the ability to generate OVERSET and/or OVERESET bits is typically restricted to the production test and thus the chip manufacturer, it may also be given to producers that implement a chip in a product, who, in this case, can make their own or additional markings.

Depending on the realization and on the exact difference between e.g. SET and OVERSET, adjusting the threshold during read operations may be used to distinguish between SET and OVERSET without actually reprogramming the data block. This will be explained with reference to FIG. 5.

A write command is issued in the following way: The write circuit 22 issues a write command with a specific address ADDI and the value that should be written into the cell, called PROGVALUE. The selection circuit 3 selects the specific cell 4 accordingly and their respective drive circuit 31 with the associated forcing circuit 32. The forcing circuit 32 provided different physical parameters depending on the state to be set.

If the value is for example RESET, the cell 4 should be reset, which means that it should transfer to a state where the resistance of the cell 4 is high. Accordingly, the drive circuit uses the forcing circuit 32 to a provide high voltage of a given polarity to the cell 4, which should make the cell 4 high resistive. Choosing the respective voltage, the write circuit may provide a first physical parameter, in this case voltage, to the cell such that a normal read circuit can read, in this case identified, by the regular read circuit. This is the case if PROGVALUE is SET or RESET. In contrast, if PROGVALUE is OVERSET or OVERRESET, the programmed values can only be identified by the read circuit 2 using non-regular conditions, but not using regular conditions.

FIG. 3 shows an aspect of the comparison circuit 71. The comparison circuit 71 comprises a XOR gate 72 and a demultiplexer 73. The XOR gate 72 receives as inputs the signals CONTENT and PROGVALUE. If the CONTENT and the PROGVALUE are not equal, the XOR outputs the signal VALID as ‘1’. This means that the respective cell 4 was either OVERSET or OVER-RESET. The signal of CONTENT is received by the 2:1 demultiplexer 73, which outputs the signal DATUM. The output equals the CONTENT if VALID is ‘1’, whereas the output equals the value DEF, which is a default value that is pre-determined by the user of the non-regular read conditions.

FIG. 4 shows a method of a read under non-regular conditions. A write command in step 401 is issued with the arguments address ADDI and a value PROGVALUE, ordering to write the value PROGVALUE in the cell having the address ADDI. In a next step 402, a read command is issued to a cell having the address ADDI. The next step 403 is a decision depending on if the result RES of the read command is equal to PROGVALUE. If yes, the result of this method is considered VALID. If not, it is NOT VALID. The data need to be written at least one time according to step 401 but the reading according to step 402 respectively step 403 can be done several times based on the once written data.

FIG. 5 shows a read circuit 2, a write circuit 22, a selection circuit 3, a drive circuit 31, a forcing circuit 32, a cell 4, a current-to-voltage converter 5, a sense amplifier 6 and a reference voltage generator 16. Blocks with same reference numbers as in previous Figures may be the same blocks but used in a different way. The read circuit 2 issues a read command together with a specific address ADDI, which indicates a specific memory cell 4. The read command is received by the selection circuit 3.

The selection circuit 3 selects the cell 4 associated with the address ADDI and activates the cell 4. The resistive memory cell 4 is activated, typically with a help of a selection transistor, such that a current may flow through the dielectric material, depending on the state of the cell 4. If the cell is in a SET state, a high current flows. The current through the selected cell 4 is received by the current-to-voltage converter 5, which outputs a voltage to the sense amplifier 6. In aspects, the current-to-voltage converter 5 and the sense amplifier 6 are embodied in one circuit. The sense amplifier 6 outputs a digital value CONTENT. The CONTENT is a representation of the state of the read memory cell 4, if the current-to-voltage converter 5 and the sense amplifier 6 work properly.

The read circuit outputs a signal VSET that is a control signal to set the voltage Vthres in the reference voltage generator 16. The voltage Vthres, output by the reference voltage generator 16, is fed to the sense amplifier 6 and provides a voltage reference for the evaluation for the voltage received from the current-to-voltage converter 5. During the regular read, the voltage Vthres is set such that the sense amplifier cannot distinguish between SET and OVERSET states. E.g. Vthres is set to 0.8V and all reads of SET and OVERSET states result in voltages provided by the current to voltage converter higher than 0.8V, they are read as 1. Accordingly, it cannot distinguish between SET and OVERSET states. In this aspect, RESET and OVERRESET states are read as 0 because the output of the current to voltage converter 5 outputs voltages below the threshold. Accordingly, the first and second states are all identified as first states, in this case SET and RESET.

Under non-regular read conditions, the read circuit 2 also performs a read command by issuing a specific address. The selection circuit 3 selects the specific cell 4 accordingly. But in contrast to regular read conditions, the read circuit 7 sets the reference voltage Vthres to a value that enables the sense amplifier to distinguish between OVERSET and SET states. In the example above, Vthres is set 0.95 V and only the OVERSET states result in an output voltage higher than 0.95V. Only cells in OVERSET state are read as ‘1’, all other states like SET, RESET, OVER-RESET are read as ‘0’. Thus, the OVERSET state in the cell 4 is identified as OVERSET state, enabled by the non-regular conditions.

In one example, where 0 represents a RESET state, 1 represents a SET state, and $ represents an OVERSET state, the block state 010$$100 reads as 01011100 under normal read conditions, thereby using the read circuit 2. A second read is performed, with slightly altered read conditions, by the help of the read circuit 2. The same block's state 010$$100 reads 00011000 if the read conditions are slightly altered, e.g. with a suitably shifted read threshold. Only the OVERSET bits appear as ‘1’s.

If the read condition e.g. depends on a comparison with a voltage or current threshold, the threshold may be altered, shifted to higher or lower values. The hidden information gets revealed without programming, in particular without writing followed by reading. The information gets revealed without actually changing the state of the block.

Again, changing the read threshold may or may not be available for normal users. If it is not available, the information is hidden and only readable by the ones who know how to perform the secret read.

In another realization, actually SET and OVERSET cannot be differentiated at all using a read, even with an adapted threshold. Either the read threshold cannot be shifted far enough in the realized hardware, or the distributions of SET and OVERSET are overlapping. In this case, one option is to use the method described above with write followed by read, which employs a programming step to reveal the hidden information., as discussed above with reference to FIG. 2.

In some aspects, no extra hardware may be required but anyway existing RRAM circuitry may be reused. In other aspects, there is extra circuitry provided.

An application may be hiding, or just storing, additional information on chip. This may provide additional methods to uniquely identify or mark a genuine chip and thus may help to detect chip cloning, to detect chip swapping, or to identify chips of unknown source.

The writing of the data with overset or over-reset values can be done in one step combined with the initial forming as explained above.

An exemplary application is performed by a passport producer. During the production of a passport, some memory elements with specific addresses are over-set or over-reset. Only the passport producer knows which specific memory cells are over-set or over-reset. These hidden memory cells are read with the help of the read circuit. The read circuit selects an over-reset cell and writes the cell with a value that usually would set the cell. In a subsequent read command, the content of the same cell is read. If read content of the cell shows that the cell is in the set state, it becomes clear that the cell was not over-reset.

A following possible attack should be prevented: a falsifier may read, write, read the all memory cells of a chip to find all over-set and over-reset bits in an original chip. He then uses a new chip and over-writes and over-sets the same bits on a new memory chip. A new fake passport has been equipped with the new memory chip. The falsifier aims that the new fake passport will pass the checks because the secret read circuits will find the same over-set and over-reset memory locations as in the original chip.

The following methods may be used to prevent this:

In one aspect, over-setting respectively over-resetting may be done by an internal forcing circuit that provides an extensive voltage or an extensive current. The access to this force-circuit or to the voltage/current generator circuit may be password-protected such that the falsifier does not know how to over-set respectively over-reset cells.

Alternatively or additionally, after production of the chip including over-setting and over-resetting, the voltage generation circuit or the forcing circuit may be disabled permanently such that the falsifier cannot use the internal circuits to over-set and over-reset. The disabling may be done e.g. by metal-fuse or electrical fuse.

Each chip may have an individual over-set/over-reset pattern, that e.g. depends on the passport number, name or any other passport-specific data. In one example, a chip in a passport was swapped with a manipulated different chip, but the hidden “watermark” information of this swapped chip does not match to the passport's serial number.

The access to new chips will be restricted. Producer of memory chips will only sell to customers that produce passports. A falsifier cannot use chips directly from production but has to use chips from other passports. He may use the chip of one passport being stolen or being declared to be stolen and manipulate the memory cells like described above and put the chip into a fake passport. However, the falsifier faces the problem that the chip from the stolen passport has cells that cannot be set or reset but are needed for the regular usage of the chip.

In a further example, a chip is detected that has been erased or overwritten by an adversary aiming to use the chip in a different way than intended by the original producer, e.g. for chip tuning. However, the hidden “watermark” tracking information, provided by over-set and over-reset memory cells, is still intact and can be read by the secret read circuit. If the over-set and over-reset memory cells provide a check-sum for the content of the other memory cells, the manipulation by the adversary can be detected.

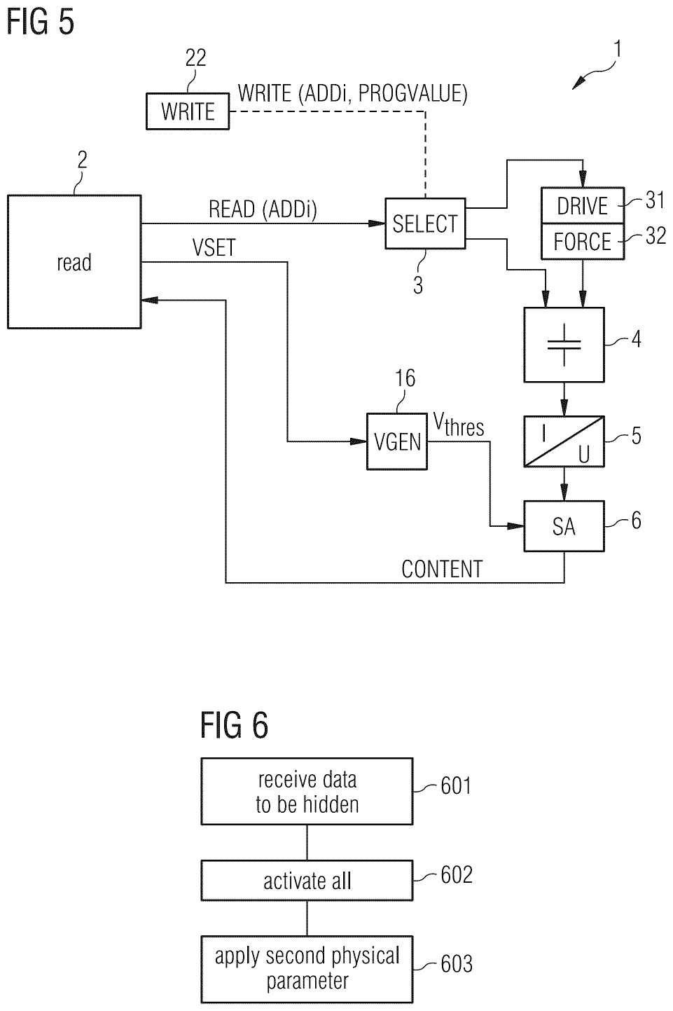

FIG. 6 shows a method for hiding data in an integrated circuit. The integrated circuit may comprise a resistive random memory access cells 4 and a write circuit 22 for the cells 4. The write circuit is configured for activating a cell and applying a first physical parameter to the cell to set the cell into a state (SET, RESET) that can be identified by a read circuit. The write circuit may alternatively activate a cell 4 and applying a second physical parameter to the cell 4 to set the cell 4 into a state (OVERSET, OVERRESET) that is not readable by a regular read circuit but readable under non-regular read conditions.

The method comprises the step 601 of receiving data to be hidden. In the step 602, the cells 4 is activated by the write circuit 22. The write circuit 22 applies the second physical parameter to the cell 4 depending on the received data in step 603.

1. A method for hiding data in an integrated circuit including random-access memory cells and a write circuit for the cells configured to selectively (i) activate a cell and apply a first physical parameter to the cell to set the cell into a first state that is identified as first state read under regular conditions, and (ii) activate a cell and apply a second physical parameter to the cell to set the cell into a second state that is identified as first state under regular read condition and is identified as second state under non-regular read conditions, the method comprising:
receiving data to be hidden;
activating the write circuit to activate the cell; and
applying the second physical parameter to the cell depending on the received data.

2. The method according to claim 1, wherein the non-regular read condition comprises:
first writing to the cell by applying a first parameter to the cell to set the cell in the first state;
then reading content of the cell; and
comparing the content of the cell with the first parameter.

3. The method according to claim 1,
wherein the regular read conditions comprise a first threshold for a sense amplifier connected to the cell, and
wherein the non-regular read conditions comprise a second threshold for a sense amplifier connected to the cell.

4. The method according to claim 2, wherein the integrated circuit further comprises:
a drive circuit for the cells to:
form cells,
set cells,
reset cells, and
over-set and/or over-reset cells,
wherein set cells are resettable, reset cells are settable, over-set cells are not resettable, and over-reset cells are not settable.

5. The method according to claim 2, wherein the integrated circuit comprises a forcing circuit to apply a voltage and/or a current to the cells, wherein a voltage and/or current level depends on whether the cell is being formed, set, reset, over-set, or over-reset.

6. The method according to claim 2, wherein the non-regular read conditions comprise:
reading the content of a cell;
then writing to the cell by applying a first parameter the cell to set the cell in the first state;
then reading the content of the cell; and
comparing the content of the cell with the first parameter.

7. The method according to claim 1, wherein the non-regular conditions are access-protected.

8. The method according to claim 1, wherein the non-regular conditions are permanently disablable.

9. The method according to claim 1, wherein the random access memory cells are resistive random-access memory cells.

10. An integrated circuit, comprising:
random-access memory cells;
a write circuit for the cells to selectively:
(i) activate a cell and apply a first physical parameter to the cell to set the cell into a first state that is identified as first state read under regular conditions; and
(ii) activate a cell and apply a second physical parameter to the cell to set the cell into a second state that is identified as first state under regular read condition and is identified as second state under non-regular read conditions,
wherein a plurality of cells are in the second state.

11. The integrated circuit according to claim 10, wherein the non-regular conditions are access-protected.

12. The integrated circuit according to claim 11, wherein the non-regular conditions are permanently disablable.

13. The integrated circuit according to claim 10, wherein the random-access memory cells are resistive random-access memory cells.
